(19) United States
(12) Patent Application Publication
(10) Pub. No.: US 2026/0076069 A1
(43) Pub. Date: Mar. 12, 2026

(54) ENCAPSULATION LAYER AND ELECTRONIC DEVICE HAVING THE SAME

(71) Applicant: Samsung Display Co., Ltd., Yongin-si (KR)

(72) Inventors: SEULGEE LEE, Yongin-si (KR); JONGWOO KIM, Yongin-si (KR); SOYOUNG OH, Yongin-si (KR); HYUNSUP YOON, Yongin-si (KR); WOOSUK JUNG, Yongin-si (KR); JAEHEUNG HA, Yongin-si (KR)

(21) Appl. No.: 19/187,111

(22) Filed: Apr. 23, 2025

(30) Foreign Application Priority Data
Sep. 6, 2024 (KR) 10-2024-0121619

(51) Int. Cl. H10K 59/80; H10K 59/38; H10K 102/00

(52) U.S. Cl. CPC H10K 59/873; H10K 59/38; H10K 59/879; H10K 2102/351

(57) ABSTRACT

An electronic device includes a display layer including emissive areas each including a light emitting element, and a non-emissive area which is adjacent to the emissive areas, an encapsulation layer which is on the display layer, the encapsulation layer defining a concave pattern or a convex pattern which overlaps an emissive area among the emissive areas together with having a width of about 40 micrometers to about 60 micrometers in a direction along the display layer and having a first refractive index, and an optical layer which is on the encapsulation layer and has a second refractive index different from the first refractive index.

This application claims priority to Korean Patent Application No. 10-2024-0121619 filed on Sep. 6, 2024, and all the benefits accruing therefrom under 35 U.S.C. § 119, the disclosures of which are incorporated by reference herein in their entireties.

### BACKGROUND

### (1) Field

Embodiments of the present disclosure described herein relate to an electronic device. More particularly, embodiments of the present disclosure relate to an electronic device with improved light extraction efficiency.

### (2) Description of the Related Art

Multimedia electronic devices, such as a television, a mobile phone, a tablet computer, a computer, a car navigation device, a game machine, and the like, include a display panel for displaying an image. The display panel includes light emitting elements and circuits for driving the light emitting elements. Depending on voltages applied from the circuits, the light emitting elements included in the display panel emit light and generate an image. Studies on an optical layer including a plurality of layers having different refractive indexes to improve the optical reliability of the display panel are being conducted.

### SUMMARY

Embodiments of the present disclosure provide an electronic device for improving light extraction efficiency and preventing mixing of colored light provided to the outside to enhance display quality.

According to an embodiment, an electronic device includes a display layer including emissive areas in each of which a light emitting element is disposed, and a non-emissive area which is adjacent to the emissive areas, an encapsulation layer which is disposed on the display layer and which includes a concave pattern or a convex pattern which overlaps an emissive area among the emissive areas, and an optical layer disposed on the encapsulation layer. A first refractive index of the encapsulation layer and a second refractive index of the optical layer are different from each other, and the concave pattern or the convex pattern has a width of about 40 micrometers (μm) to 60 μm.

According to an embodiment, an electronic device includes a display layer including emissive areas in each of which a light emitting element is disposed and a non-emissive area adjacent to the emissive areas, an encapsulation layer which is disposed on the display layer and which includes a concave pattern which overlaps an emissive area among the emissive areas and is recessed toward the light emitting element, and an optical layer which is disposed on the encapsulation layer and which has a refractive index greater than a refractive index of the encapsulation layer.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device illustrated in FIG. 1 according to an embodiment of the present disclosure.

FIG. 3 is a cross-sectional view of a display module illustrated in FIG. 2 according to an embodiment of the present disclosure.

FIG. 4 is an enlarged cross-sectional view of the display module according to an embodiment of the present disclosure.

FIG. 5 is an enlarged plan view of a portion of the display module according to an embodiment of the present disclosure.

FIG. 6A is a cross-sectional view of the display module corresponding to line I-I′ illustrated in FIG. 5 according to an embodiment of the present disclosure.

FIG. 6B is an enlarged view of area AA′ illustrated in FIG. 6A.

FIG. 7A is a cross-sectional view of a display module corresponding to line I-I′ illustrated in FIG. 5 according to an embodiment of the present disclosure.

FIG. 7B is an enlarged view of area BB′ illustrated in FIG. 7A.

FIG. 8 is a cross-sectional view of a display module corresponding to line I-I′ illustrated in FIG. 5 according to an embodiment of the present disclosure.

FIG. 9 is a cross-sectional view of a display module corresponding to line I-I′ illustrated in FIG. 5 according to an embodiment of the present disclosure.

FIG. 10 is a block diagram illustrating an electronic device according to an embodiment of the present disclosure.

FIG. 11 is a schematic view of electronic devices according to embodiments of the present disclosure.

### DETAILED DESCRIPTION

Various changes can be made to the present disclosure, and various embodiments of the present disclosure may be implemented. Thus, embodiments are illustrated in the drawings and described as examples herein. However, it should be understood that the present disclosure is not to be construed as being limited thereto and covers all modifications, equivalents, and alternatives falling within the spirit and scope of the present disclosure.

In this specification, when a component (or, an area, a layer, a part, etc.) is referred to as being related to another element such as being “on”, “connected to” or “coupled to” another component, this means that the component may be directly on, connected to, or coupled to the other component or a third component may be present therebetween. In contrast, when a component (or, an area, a layer, a part, etc.) is referred to as being related to another element such as being “directly on,” “directly connected to” or “directly coupled to” another component, this means that no other component or third component is present therebetween.

Identical reference numerals refer to identical components. Additionally, in the drawings, the thicknesses, proportions, and dimensions of components are exaggerated for effective description. Within the Figures and the text of the disclosure, a reference number indicating a singular form of an element may also be used to reference a plurality of the element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or. ” As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below,” “under,” “above,” and “over” are used to describe a relationship between components illustrated in the drawings. The terms are relative concepts and are described based on directions illustrated in the drawing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise,” “include,” and “have” when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

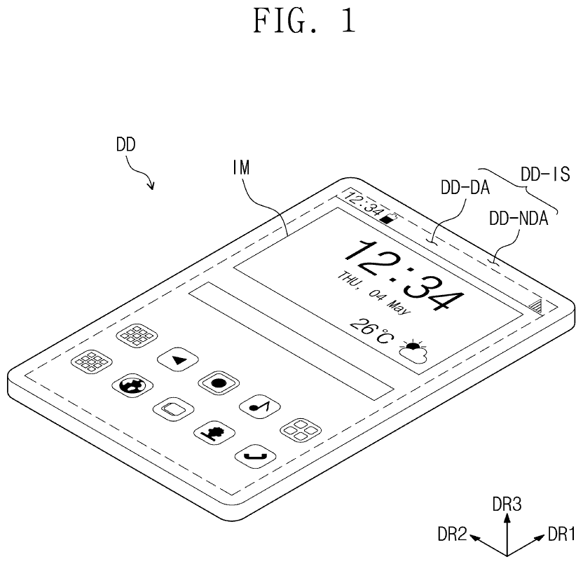

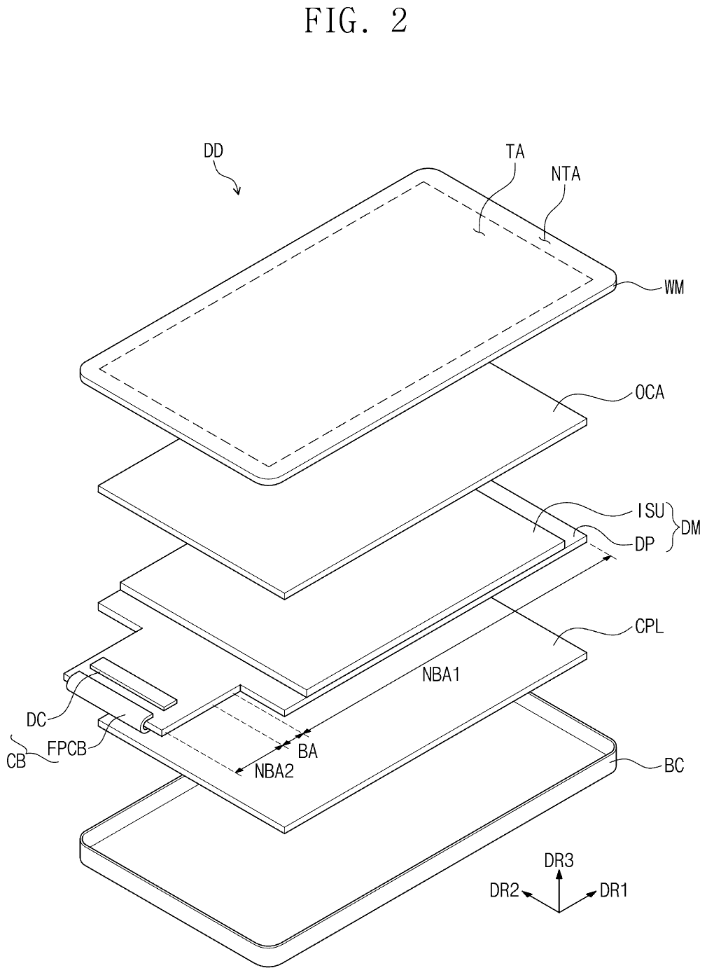

FIG. 1 is a perspective view of an electronic device DD according to an embodiment of the present disclosure. FIG. 2 is an exploded perspective view of the electronic device DD illustrated in FIG. 1 according to an embodiment of the present disclosure.

Referring to FIG. 1, in this specification, a mobile phone terminal is illustrated as an example of the electronic device DD. The electronic device DD according to the present disclosure may be applied to small and medium-sized electronic devices such as a tablet computer, a car navigation device, a game machine, a smart watch, and the like, as well as large electronic devices such as a television, a monitor, and the like.

The electronic device DD, when viewed from above a plane (in a plan view), may have a rectangular shape having long sides extending in a first direction DR1 and short sides extending in a second direction DR2 which crosses the first direction DR1. However, without being limited thereto, the electronic device DD may have various planar shapes such as a circular shape, a polygonal shape, and the like when viewed from above the plane.

Hereinafter, a direction substantially perpendicular to a plane defined by the first direction DR1 and the second direction DR2 is defined as a third direction DR3. The expression “when viewed from above the plane” used herein may mean that it is viewed along the third direction DR3. A thickness of the electronic device DD and various components or layers thereof may be defined along the third direction DR3, that is, a thickness direction.

The electronic device DD may be a rigid or a flexible electronic device. The term “flexible” used herein may mean a property of being curved and may include everything from a structure capable of being fully folded to a structure capable of being curved to a level of several nanometers. For example, the flexible electronic device DD may include a curved electronic device, a rollable electronic device, or a foldable electronic device.

The electronic device DD may display an image IM through a display surface DD-IS. Icon images are illustrated as an example of the image IM. The display surface DD-IS may be parallel to the plane defined by the first direction DR1 and the second direction DR2.

The display surface DD-IS may include a display area DD-DA as a planar area in which the image IM is displayed and a non-display area DD-NDA which is adjacent to the display area DD-DA. The non-display area DD-NDA may be a planar area in which an image IM is not displayed. However, without being limited thereto, the non-display area DD-NDA may be adjacent to one side of the display area DD-DA or may be omitted.

Referring to FIG. 2, the electronic device DD may include a window WM, an upper adhesive layer OCA, a display module DM, a lower member CPL, and a receiving member BC.

The window WM may be disposed over the display module DM and may transmit an image IM provided from the display module DM to the outside (e.g., the outside of the electronic device DD). The window WM may include a transmissive area TA and a non-transmissive area NTA. The transmissive area TA may overlap the display area DD-DA illustrated in FIG. 1 and may have a shape (e.g., a planar shape) corresponding to the display area DD-DA. Although not illustrated, the window WM may include a base window layer and functional layers which are disposed on the base window layer. The functional layers may include a protective layer, an anti-fingerprint layer, and the like.

The base window layer of the window WM may be formed of (or include) glass, sapphire, or plastic. The base window layer of the window WM may include an optically clear insulating material. For example, the base window layer of the window WM may include a glass or plastic film or may include a glass substrate and a plastic film coupled to each other through an adhesive.

The non-transmissive area NTA may overlap the non-display area DD-NDA illustrated in FIG. 1 and may have a shape corresponding to the non-display area DD-NDA. The non-transmissive area NTA may be an area having a lower light transmittance than the transmissive area TA. The non-transmissive area NTA may be defined in a partial area of the base window layer of the window WM by a bezel pattern, and the area of the base window layer where the bezel pattern is not disposed may be defined as the transmissive area TA. However, without being limited thereto, the non-transmissive area NTA may be omitted.

The display module DM may be disposed under the window WM. The display module DM may include a display panel DP and an input sensor ISU.

The display panel DP may be one of a liquid crystal display panel, an electrophoretic display panel, a microelectromechanical system (MEMS) display panel, an electrowetting display panel, an organic light emitting display panel, an inorganic light emitting display panel, and a quantum dot light emitting display panel. However, the display panel DP may not be particularly limited thereto. Hereinafter, the display panel DP will be described as an organic light emitting display panel.

The input sensor ISU may include one of a capacitive sensor, an optical sensor, an ultrasonic sensor, and an electromagnetic induction sensor. The input sensor ISU may be formed (or provided) on the display panel DP through a continuous process, or may be manufactured separately from the display panel DP and then attached to the upper side of the display panel DP such as through an adhesive layer, and is not limited to any one embodiment.

The display module DM may include a circuit board CB. The circuit board CB may include a driver chip DC and a flexible circuit board FPCB. Although FIG. 2 illustrates an embodiment in which the driver chip DC is mounted on the display panel DP, the present disclosure is not limited thereto. The driver chip DC may generate an electrical signal such as a drive signal used for an operation of the display panel DP, based on an electrical signal such as a control signal transferred from the flexible circuit board FPCB.

The display panel DP may include a bending portion BA at which the display panel DP is bendable, and one or more of a non-bending portion such as a first non-bending portion NBA1 and a second non-bending portion NBA2 which are spaced apart from each other in the first direction DR1 with the bending portion BA therebetween.

The bending portion BA may be defined as a portion of the display panel DP which is bendable with respect to a virtual bending axis extending in the second direction DR2. The first non-bending portion NBA1 may be an area of the display panel DP which overlaps the transmissive area TA, and the second non-bending portion NBA2 may be defined as an area of the display panel DP at which the flexible circuit board FPCB is connected to the display panel DP. When the bending portion BA is bent with respect to the bending axis, a portion of the flexible circuit board FPCB and the driver chip DC may be bent in the direction toward the rear surface of the display panel DP (e.g., in a direction opposite to DR3 in FIG. 2) and may be disposed under the display panel DP. Although not illustrated, additional components for compensating for a step formed between the circuit board CB and the rear surface of the display panel DP by the bending portion BA may be disposed.

According to an embodiment, the width of the first non-bending portion NBA1 in the second direction DR2 may be greater than the widths of the bending portion BA and the second non-bending portion NBA2 in the second direction DR2. However, without being limited thereto, the width of the bending portion BA in the second direction DR2 may be decreased in the direction from the first non-bending portion NBA1 to the second non-bending portion NBA2 and is not limited to any one embodiment.

The flexible circuit board FPCB may be disposed at one end of the display panel DP. The flexible circuit board FPCB may be disposed on or extend from the upper surface of the second non-bending portion NBA2 as a surface furthest along in the third direction DR3. One portion of the flexible circuit board FPCB may be disposed on the upper surface of the second non-bending portion NBA2, and another portion of the flexible circuit board FPCB which extends from the one portion may be bent and disposed on the lower surface of the second non-bending portion NBA2.

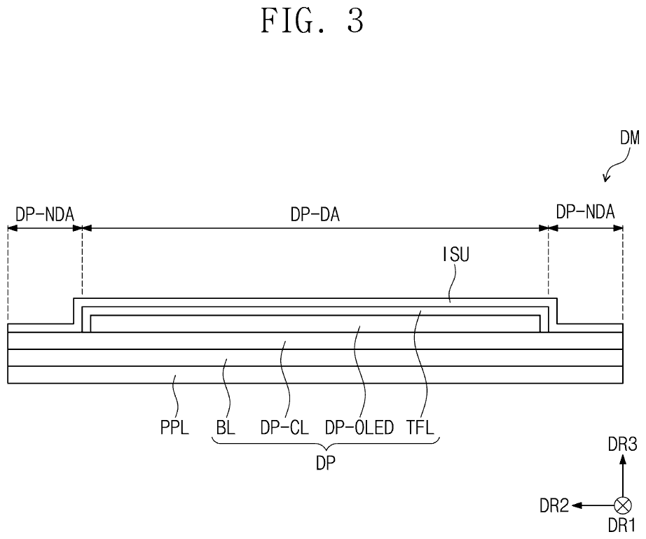

The flexible circuit board FPCB may be connected to the display panel DP at the second non-bending portion NBA2. The flexible circuit board FPCB may be electrically connected to a circuit layer DP-CL of the display panel DP which will be described with reference to FIG. 3.

Although not illustrated, the display module DM may further include an anti-reflective layer. The anti-reflective layer may decrease the reflectance of external light incident from outside the electronic device DD.

The upper adhesive layer OCA may be disposed between the window WM and the display module DM. The upper adhesive layer OCA may be disposed on or overlapping the first non-bending portion NBA1. The upper adhesive layer OCA may have a rectangular shape having long sides extending in the first direction DR1 and short sides extending in the second direction DR2. The window WM and the display module DM may be bonded to each other by the upper adhesive layer OCA.

The receiving member BC may be disposed under the display module DM. The receiving member BC may accommodate the display module DM, the upper adhesive layer OCA, and the lower member CPL to be described below and may be coupled with the window WM. The receiving member BC together with the window WM may provide an outer surface of the electronic device DD, without being limited thereto.

The lower member CPL may be disposed between the display module DM and the receiving member BC. The lower member CPL may be disposed under and overlapping the first non-bending portion NBA1. The lower member CPL may have, for example, a rectangular shape having long sides extending in the first direction DR1 and short sides extending in the second direction DR2.

FIG. 3 is a cross-sectional view of the display module DM illustrated in FIG. 2 according to an embodiment of the present disclosure.

Referring to FIG. 3, the display module DM may include the input sensor ISU, the display panel DP, and a panel protection layer PPL. The display panel DP may include a base layer BL, and the circuit layer DP-CL, a display layer DP-OLED, and an encapsulation layer TFL which are disposed on the base layer BL. The input sensor ISU may be disposed on the encapsulation layer TFL.

The display panel DP may include a display area DP-DA and a non-display area DP-NDA. The display area DP-DA of the display panel DP may correspond to the display area DD-DA illustrated in FIG. 1 and/or the transmissive area TA illustrated in FIG. 2, and the non-display area DP-NDA may correspond to the non-display area DD-NDA illustrated in FIG. 1 and/or the non-transmissive area NTA illustrated in FIG. 2.

The base layer BL may include at least one plastic film. The base layer BL may include a plastic substrate, a glass substrate, a metal substrate, or an organic/inorganic composite substrate as a flexible substrate.

The circuit layer DP-CL may include at least one intermediate insulating layer and a circuit element. The intermediate insulating layer may include at least one intermediate inorganic layer and at least one intermediate organic layer. The circuit element may include signal lines and a pixel drive circuit.

The display layer DP-OLED may include a plurality of organic light emitting diodes as light emitting elements. The display layer DP-OLED may further include an organic layer such as a pixel defining layer.

The encapsulation layer TFL may seal the display layer DP-OLED. The encapsulation layer TFL may be disposed on the display layer DP-OLED. The encapsulation layer TFL may overlap the display area DP-DA and the non-display area DP-NDA. The encapsulation layer TFL may overlap at least a portion of the non-display area DP-NDA. For example, the encapsulation layer TFL may include a thin film encapsulation layer. The thin film encapsulation layer may include a stack structure of an inorganic layer, an organic layer, and an inorganic layer. The encapsulation layer TFL may protect the display layer DP-OLED from foreign matter such as moisture, oxygen, and dust particles. However, without being limited thereto, the encapsulation layer TFL may further include an additional insulating layer in addition to the thin film encapsulation layer.

In an embodiment of the present disclosure, an encapsulation substrate may be provided instead of the encapsulation layer TFL. In this case, the encapsulation substrate may be opposite the base layer BL, and the circuit layer DP-CL and the display layer DP-OLED may be disposed between the encapsulation substrate and the base layer BL.

The input sensor ISU may be directly disposed on the display panel DP. The expression “component A is directly disposed on component B” used herein means that a separate layer is not disposed between component A and component B. In this embodiment, the input sensor ISU may be manufactured together with the display panel DP through a continuous process. However, the spirit and scope of the present disclosure is not limited thereto, and the input sensor ISU may be provided as a separate panel and may be coupled with the display panel DP through an adhesive layer. For example, the input sensor ISU may be omitted.

The panel protection layer PPL may be disposed under the display panel DP. The panel protection layer PPL may protect the bottom of the display panel DP. The panel protection layer PPL may include a flexible plastic material. For example, the panel protection layer PPL may include polyethylene terephthalate (PET).

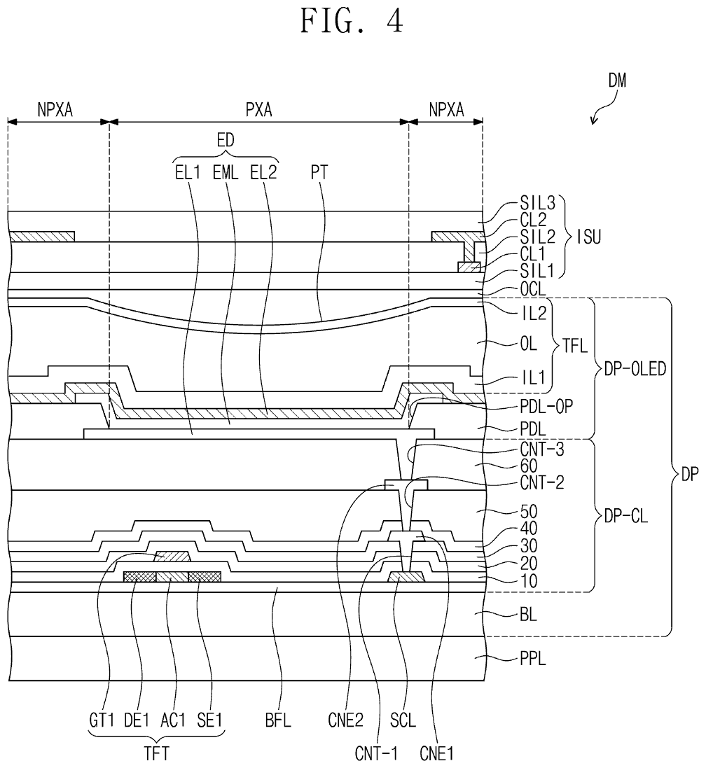

FIG. 4 is a cross-sectional view of the display module DM according to an embodiment of the present disclosure. The structure of FIG. 4 may be disposed in the display area DP-DA of the display module DM.

For example, a cross-section which corresponds to a single one of an emissive area PXA and a non-emissive area NPXA which is around the emissive area PXA are illustrated in FIG. 4. However, without being limited thereto, a plurality of emissive areas PXA may be provided.

For example, a light emitting element ED and a single one of a transistor TFT which is connected to the light emitting element ED are illustrated in FIG. 4. However, substantially, the light emitting element ED may be connected to a plurality of transistors TFT and at least one capacitor. In addition, the transistor TFT of FIG. 4 is described as a silicon transistor. However, the transistor TFT may be a metal oxide transistor.

Referring to FIG. 4, the display module DM may include the input sensor ISU, the display panel DP, and the panel protection layer PPL. The display panel DP may include the base layer BL, the circuit layer DP-CL, the display layer DP-OLED, and the encapsulation layer TFL.

The base layer BL may provide a base surface on which the circuit layer DP-CL is disposed. The base layer BL may be a rigid substrate or may be a flexible substrate capable of being bent, folded, or rolled. The base layer BL may include a plastic substrate, a glass substrate, a metal substrate, or an organic/inorganic composite substrate as the flexible substrate.

The base layer BL may have a multi-layer structure. For example, the base layer BL may include a first synthetic resin layer, an inorganic layer having a multi-layer structure or a single-layer structure, and a second synthetic resin layer disposed on the inorganic layer having the multi-layer structure or the single-layer structure. Each of the first synthetic resin layer and the second synthetic resin layer may include a polyimide-based resin, but is not particularly limited.

The circuit layer DP-CL may be disposed on the base layer BL. The circuit layer DP-CL may include an insulating layer, a semiconductor pattern, a conductive pattern, a signal line, and a pixel drive circuit. For example, the circuit layer DP-CL may include a buffer layer BFL, first to sixth insulating layers 10, 20, 30, 40, 50, and 60, a signal transmission area SCL as representing a signal line (or signal transmission line), and a plurality of connecting electrodes CNE1 and CNE2.

The buffer layer BFL may be disposed on the base layer BL. The buffer layer BFL may prevent diffusion of metal atoms or impurities from the base layer BL to the semiconductor pattern on the buffer layer BFL. A back metal layer (not shown) may be additionally disposed between the base layer BL and the buffer layer BFL. The back metal layer may be disposed under the transistor TFT to be described below and may block external light from reaching the transistor TFT.

The semiconductor pattern may be disposed on the buffer layer BFL. The semiconductor pattern may include a silicon semiconductor. For example, the silicon semiconductor may include amorphous silicon or polycrystalline silicon. For example, the semiconductor pattern may include low-temperature polycrystalline silicon.

The semiconductor pattern may include first areas having a high conductivity and a second area having a low conductivity. The first areas may be doped with an N-type dopant or a P-type dopant. A P-type transistor may include a doped area doped with a P-type dopant, and an N-type transistor may include a doped area doped with an N-type dopant. The second area may be an un-doped area or may be an area more lightly doped than the first areas.

The first areas may have a higher conductivity (e.g., electrical conductivity) than the second area and may substantially serve as electrodes or signal lines. The second area may substantially correspond to an active area (or, a channel) of the transistor TFT. In other words, one portion of the semiconductor pattern may be the active area of the transistor TFT, another portion may be a source or drain of the transistor TFT, and the other portion may be a connecting electrode or a connecting signal line.

The transistor TFT may include a source area (or, a source) SE1, an active area (or, a channel) AC1, a drain area (or, a drain) DE1, and a gate GT1. The source area SE1, the active area AC1, and the drain area DE1 of the transistor TFT may be formed from the semiconductor pattern to be respective portions or areas thereof. The source area SE1 and the drain area DE1 may extend from the active area AC1 in opposite directions on the cross-section, such as along a planar direction (e.g., any of a number of directions along the plane defined by the first direction DR1 and the second direction DR2. In FIG. 4, a portion of the signal transmission area SCL formed from the semiconductor pattern is illustrated. Although not separately illustrated, the signal transmission area SCL may be connected to the drain DE1 of the transistor TFT when viewed from above the plane. That is, the semiconductor pattern and the signal transmission area SCL may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The first insulating layer 10 may be disposed on the buffer layer BFL. The first insulating layer 10 may cover the source SE1, the active area AC1, the drain DE1, and the signal transmission area SCL of the transistor TFT which are disposed on the buffer layer BFL.

The first insulating layer 10 may include an inorganic layer and/or an organic layer and may have a single-layer structure or a multi-layer structure. The inorganic layer may include at least one of aluminum oxide, titanium oxide, silicon oxide, silicon nitride, silicon oxy nitride, zirconium oxide, and hafnium oxide. In this embodiment, the first insulating layer 10 may be a single silicon oxide layer. Not only the first insulating layer 10 but also the insulating layers of the circuit layer DP-CL which will be described below may be inorganic layers and/or organic layers and may have a single-layer structure or a multi-layer structure. The inorganic layers may include at least one of the aforementioned materials, but are not limited thereto.

The gate GT1 of the transistor TFT may be disposed on the first insulating layer 10. The gate GT1 may be a portion of a metal pattern or a conductive material layer. The gate GT1 may overlap the active area AC1. The gate GT1 may function as a mask in a process of doping the semiconductor pattern, within a method of providing the electronic device DD. The gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but is not particularly limited thereto.

The second insulating layer 20 may be disposed on the first insulating layer 10 and may cover the gate GT1. The third insulating layer 30 may be disposed on the second insulating layer 20.

The first connecting electrode CNE1 may be disposed on the third insulating layer 30. The first connecting electrode CNE1 may be connected to the signal transmission area SCL through a first contact hole CNT-1 penetrating the first to third insulating layers 10, 20, and 30. The fourth insulating layer 40 may be disposed on the third insulating layer 30 and may cover the first connecting electrode CNE1. The fourth insulating layer 40 may be an organic layer.

The fifth insulating layer 50 may be disposed on the fourth insulating layer 40. The second connecting electrode CNE2 may be disposed on the fifth insulating layer 50. The second connecting electrode CNE2 may be connected to the first connecting electrode CNE1 through a second contact hole CNT-2 penetrating the fourth insulating layer 40 and the fifth insulating layer 50. The fifth insulating layer 50 may be an organic layer.

The sixth insulating layer 60 may be disposed on the fifth insulating layer 50 and may cover the second connecting electrode CNE2. The sixth insulating layer 60 may be an organic layer. The stack structure of the first to sixth insulating layers 10, 20, 30, 40, 50, and 60 is merely illustrative, and an additional conductive layer and an additional insulating layer may be further disposed in addition to the first to sixth insulating layers 10, 20, 30, 40, 50, and 60. One or more of the first to sixth insulating layers 10, 20, 30, 40, 50, and 60 may be referred to as ‘an insulating layer.’

The display layer DP-OLED may be disposed on the circuit layer DP-CL. The display layer DP-OLED may include the light emitting element ED and a pixel defining layer PDL.

The light emitting element ED may include an organic light emitting element, an inorganic light emitting element, an organic-inorganic light emitting element, a quantum-dot light emitting element, a micro LED light emitting element, or a nano LED light emitting element. However, embodiments are not limited thereto, and the light emitting element ED may include various embodiments as long as depending on an electrical signal, light is generated or the amount of light is controlled.

The light emitting element ED may include a first electrode (or, an anode) EL1, an emissive layer EML, and a second electrode (or, a cathode) EL2. The first electrode EL1 may be disposed on the sixth insulating layer 60. The first electrode EL1 may be a transmissive electrode, a transflective electrode, or a reflective electrode. The first electrode EL1 may include a reflective layer formed of metal or a compound thereof and a transparent or translucent electrode layer formed on the reflective layer. The transparent or translucent electrode layer may include at least one selected from indium tin oxide (ITO), indium zinc oxide (IZO), indium gallium zinc oxide (IGZO), zinc oxide (ZnOx), or indium oxide (In₂O₃) and aluminum-doped zinc oxide (AZO). For example, the first electrode EL1 may include a stack structure of ITO/Ag/ITO.

The pixel defining layer PDL may be disposed on the sixth insulating layer 60. According to an embodiment, the pixel defining layer PDL may have a property of absorbing light. For example, the pixel defining layer PDL may be black in color. The pixel defining layer PDL may include a black coloring agent. The black coloring agent may include a black dye or a black pigment. The black coloring agent may include carbon black, metal such as chromium, or oxide thereof. The pixel defining layer PDL may correspond to a light blocking pattern having light-blocking characteristics.

A solid portion of the pixel defining layer PDL may cover a portion of the first electrode EL1. For example, a pixel opening PDL-OP exposing a portion of the first electrode EL1 may be defined in the solid (or material) portion of the pixel defining layer PDL. The pixel opening PDL-OP of the pixel defining layer PDL may define the emissive area PXA. That is, a planar dimension of the emissive area PXA may correspond to a planar dimension of the pixel opening PDL-OP.

A hole control layer (not shown) may be further disposed between the first electrode EL1 and the emissive layer EML. The hole control layer may include a hole transport layer and/or a hole injection layer. An electron control layer may be further disposed between the emissive layer EL and the second electrode EL2. The electron control layer may include an electron transport layer and/or an electron injection layer.

The display layer DP-OLED may further include a capping layer. The capping layer (not shown) may be disposed on the light emitting element ED and may cover the second electrode EL2 of the light emitting element ED. The capping layer may include an organic material. The capping layer may be formed of a single layer or multiple layers. The capping layer may sufficiently protect the light emitting element ED under the capping layer from external moisture penetration or contamination, and thus the light emitting element ED with improved lifespan may be provided.

The encapsulation layer TFL may be disposed on the display layer DP-OLED. The encapsulation layer TFL may protect the display layer DP-OLED from foreign matter such as moisture, oxygen, and dust particles. The encapsulation layer TFL may include a first inorganic layer IL1, an organic layer OL, and a second inorganic layer IL2 sequentially stacked one above another. However, layers constituting the encapsulation layer TFL are not limited thereto.

The first inorganic layer IL1 and the second inorganic layer IL2 as a first inorganic encapsulation layer and a second inorganic encapsulation layer may protect the display layer DP-OLED from moisture and oxygen, and the organic layer OL as an organic encapsulation layer may protect the display layer DP-OLED from foreign matter such as dust particles. The first inorganic layer IL1 and the second inorganic layer IL2 may include a silicon nitride layer, a silicon oxy nitride layer, a silicon oxide layer, a titanium oxide layer, or an aluminum oxide layer. The organic layer OL may include an acrylic organic layer, but is not limited thereto.

According to an embodiment of the present disclosure, a pattern PT may be defined in the encapsulation layer TFL. For example, the pattern PT may be a concave pattern of the encapsulation layer TFL which is recessed toward the light emitting element ED. The upper surface of the organic layer OL may be recessed toward the light emitting element ED to form a profile of the pattern PT and the second inorganic layer IL2 may have a profile corresponding to that the recessed profile of the organic layer OL. Detailed description about the pattern PT will be given below.

An optical layer OCL may be disposed on the display panel DP. The optical layer OCL may provide a flat upper surface while following the underlying shape of the pattern PT of the encapsulation layer TFL. The optical layer OCL may include an organic material.

The input sensor ISU may be disposed on the display panel DP. The input sensor ISU may extend along the flat upper surface of the optical layer OCL. The input sensor ISU may be referred to as a sensor layer, an input sensing layer, or an input sensing panel. The input sensor ISU may include a base insulating layer SIL1, a first conductive layer CL1, a sensing insulation layer SIL2, a second conductive layer CL2, and a cover layer SIL3.

The base insulating layer SIL1 may be directly disposed on the display panel DP. The base insulating layer SIL1 may be an inorganic material layer including at least one of silicon nitride, silicon oxy nitride, and silicon oxide. Alternatively, the base insulating layer SIL1 may be an organic material layer including an epoxy resin, an acrylic resin, or an imide-based resin. The base insulating layer SIL1 may have a single-layer structure or may have a multi-layer structure stacked in the third direction DR3.

Each of the first conductive layer CL1 and the second conductive layer CL2 may have a single-layer structure or may have a multi-layer structure stacked in the third direction DR3. Although not illustrated, each of the first conductive layer CL1 and the second conductive layer CL2 may include a sensing pattern and/or a bridge pattern having a mesh structure when viewed from above the plane. That is, solid portions may be spaced apart from each other to define gaps or openings therebetween, where the solid portions together with the opening provide the mesh structure.

A conductive layer within the input sensor ISU which has a single-layer structure (e.g., a monolayer) may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), or indium zinc tin oxide (IZTO). In addition, the transparent conductive layer may include a conductive polymer such as PEDOT, a metal nano-wire, or graphene.

A conductive layer within the input sensor ISU which has a multi-layer structure may include metal layers. The meal layers may have, for example, a three-layer structure of titanium/aluminum/titanium. The conductive layer having the multi-layer structure may include at least one metal layer and at least one transparent conductive layer.

The sensing insulation layer SIL2 may be disposed between the first conductive layer CL1 and the second conductive layer CL2. The cover layer SIL3 may be disposed on the sensing insulation layer SIL2 and may cover the second conductive layer CL2. The cover layer SIL3 may decrease or remove a probability that the second conductive layer CL2 will be damaged in a subsequent process, such as during the method of providing the electronic device DD. In an embodiment of the present disclosure, the input sensor ISU may not include (e.g., may exclude or omit) the cover layer SIL3.

The sensing insulation layer SIL2 and the cover layer SIL3 may include an inorganic film. The inorganic film may include at least one of aluminum oxide, titanium oxide, silicon oxide, silicon nitride, silicon oxy nitride, zirconium oxide, and hafnium oxide.

Alternatively, the sensing insulation layer SIL2 and the cover layer SIL3 may include an organic film. For example, the organic film may include at least one of an epoxy resin, a urethane-based resin, a celluosic resin, a siloxane-based resin, a polyimide resin, a polyamide resin, and a perylene-based resin.

The panel protection layer PPL may be disposed under the display panel DP. The panel protection layer PPL may be disposed on the lower surface of the base layer BL. The panel protection layer PPL may include a flexible plastic material. For example, the panel protection layer PPL may include polyethylene terephthalate (PET). The panel protection layer PPL may protect the bottom of the display panel DP.

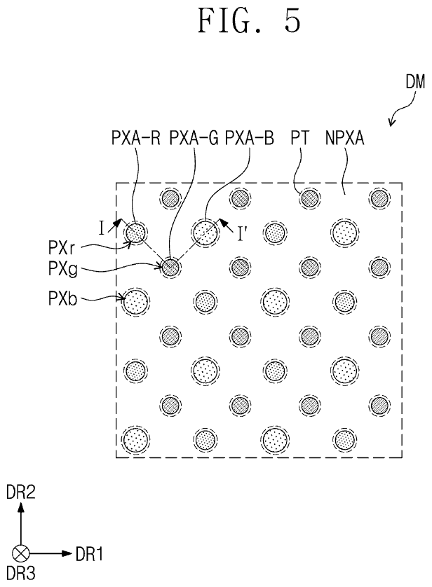

FIG. 5 is an enlarged plan view of a portion of the display module DM according to an embodiment of the present disclosure.

Referring to FIG. 5, the display module DM may include a pixel provided in plural including a plurality of pixels PXr, PXg, and PXb. The pixels PXr, PXg, and PXb may include the first pixel PXr, the second pixel PXg, and the third pixel PXb.

An emissive area may be provided in plural, such as arranged along the display area DP-DA. As planar areas of the various emissive areas, a first emissive area PXA-R may be defined in the first pixel PXr, a second emissive area PXA-G may be defined in the second pixel PXg, and a third emissive area PXA-B may be defined in the third pixel PXb. The circular planar shapes illustrated in FIG. 5 may correspond to the planar shapes of the first to third emissive areas PXA-R, PXA-G, and PXA-B, respectively. However, the planar shapes of the first to third emissive areas PXA-R, PXA-G, and PXA-B are not limited thereto. For example, the first to third emissive areas PXA-R, PXA-G, and PXA-B may have an oval shape when viewed from above the plane (e.g., in a plan view). Alternatively, the first to third emissive areas PXA-R, PXA-G, and PXA-B may have various planar shapes, such as a quadrangular shape, a polygonal shape, a triangular shape, and an irregular shape, when viewed from above the plane.

In an embodiment of the present disclosure, the first pixel PXr and the third pixel PXb may be alternately arranged one by one in both the first direction DR1 and the second direction DR2, such as along a pixel row extended along the first direction DR1 and a pixel column extended along the second direction DR2. First pixels PXr may be arranged along a first diagonal direction intersecting the first direction DR1 and/or the second direction DR2. Third pixels PXb may be arranged along a second diagonal direction intersecting the first direction DR1 and/or the second direction DR2. The first and second diagonal directions of the first pixels PXr and the third pixels PXb may be parallel to each other, without being limited thereto. The second pixel PXg provided in plural may be arranged between two first pixels PXr adjacent to each other in a respective diagonal direction and between two third pixels PXb adjacent to each other in a respective diagonal direction. Here, the second pixels PXg may alternate with first pixels PXr and with the third pixels PXb along respective diagonal directions. However, the arrangement relationship between the first to third pixels PXr, PXg, and PXb illustrated in FIG. 3 is an example, and an arrangement relationship between the first to third pixels PXr, PXg, and PXb is not particularly limited thereto. The diagonal direction may be a direction between the first direction DR1 and the second direction DR2 or a direction between the direction opposite to the first direction DR1 and the second direction DR2.

One of the first to third emissive areas PXA-R, PXA-G, and PXA-B among the emissive areas may emit first light, another one may emit second light different from the first light, and the other one may emit third light different from the first light and the second light. For example, the first emissive area PXA-R may emit red light, the second emissive area PXA-G may emit green light, and the third emissive area PXA-B may emit blue light.

In an embodiment of the present disclosure, the third emissive area PXA-B may have the largest area (e.g., planar area), and the second emissive area PXA-G may have the smallest area. However, the present disclosure is not particularly limited thereto. The planar areas of the first to third emissive areas PXA-R, PXA-G, and PXA-B may be set depending on the colors of emitted light. For example, the planar areas of the first to third emissive areas PXA-R, PXA-G, and PXA-B may be equal to one another or may be different from those in the illustrated example.

The non-emissive area NPXA may be disposed around the first to third emissive areas PXA-R, PXA-G, and PXA-B, such as within the display area DP-DA. The non-emissive area NPXA may set the boundaries between the first to third emissive areas PXA-R, PXA-G, and PXA-B. The non-emissive area NPXA may surround the first to third emissive areas PXA-R, PXA-G, and PXA-B in the plan view. A structure for preventing color mixing between the first to third emissive areas PXA-R, PXA-G, and PXA-B, for example, the pixel defining layer PDL (refer to FIG. 4) may be disposed in the non-emissive area NPXA.

The pattern PT may be provided in plural to respectively correspond to the first to third emissive areas PXA-R, PXA-G, and PXA-B. According to an embodiment of the present disclosure, the plurality of patterns PT may surround the first to third emissive areas PXA-R, PXA-G, and PXA-B when viewed from above the plane. That is, the patterns PT may have a hemispherical shape on the cross-section as illustrated in FIG. 4 and may have a circular shape on the plane as illustrated in FIG. 5. However, the present disclosure is not limited thereto, and the patterns PT may have various shapes, such as a quadrangular shape, a polygonal shape, a triangular shape, and an irregular shape, when viewed from above the plane. Here, the planar area of the pattern PT may be larger than a planar area of a respective emissive area.

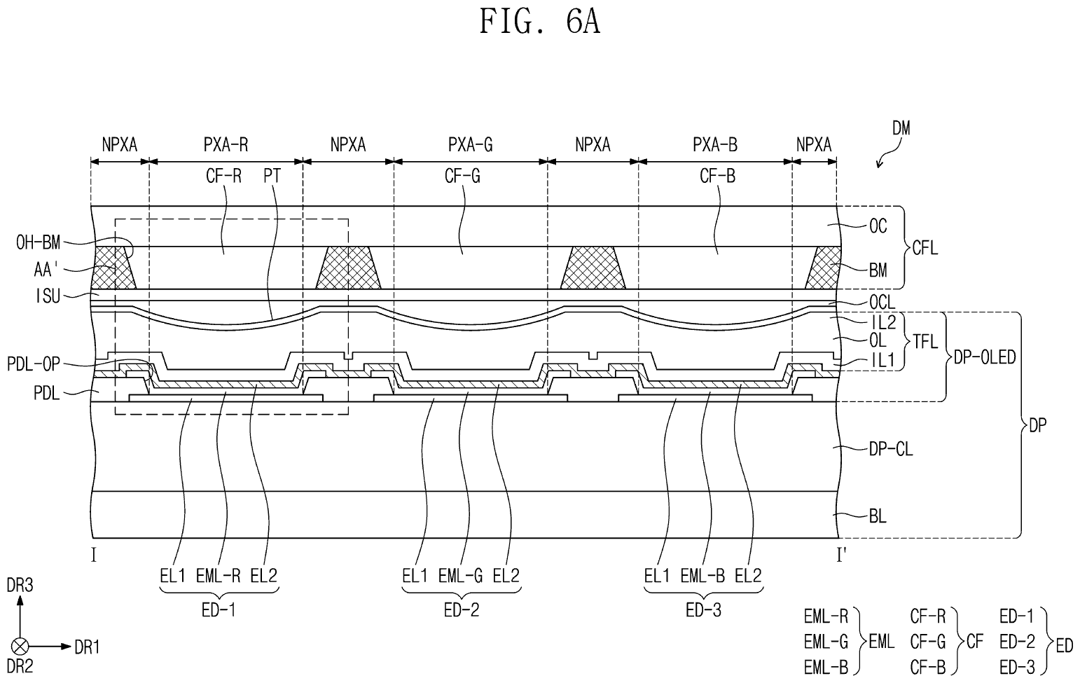

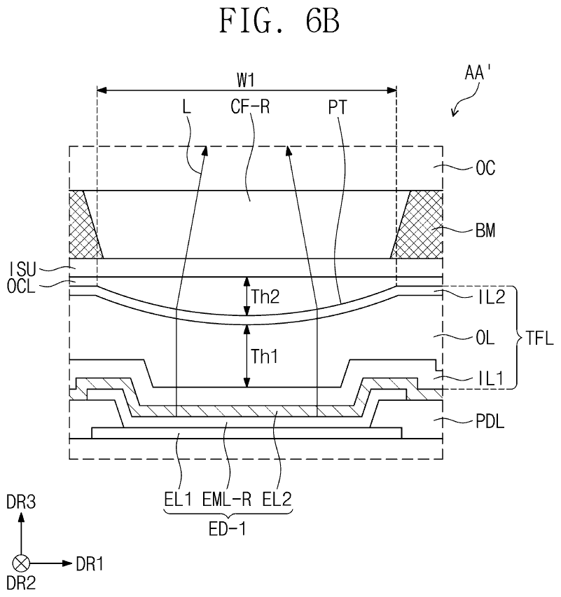

FIG. 6A is a cross-sectional view of the display module DM corresponding to line I-I′ illustrated in FIG. 5 according to an embodiment of the present disclosure. FIG. 6B is an enlarged view of area AA′ illustrated in FIG. 6A. Hereinafter, components identical/similar to the components described above will be assigned with identical/similar reference numerals, and repetitive description will be omitted.

Referring to FIG. 6A, the display module DM according to an embodiment of the present disclosure may include the display panel DP, the optical layer OCL disposed on the display panel DP, the input sensor ISU disposed on the optical layer OCL, and a color filter layer CFL disposed on the input sensor ISU.

The display panel DP may include the base layer BL, the circuit layer DP-CL, and the display layer DP-OLED sequentially stacked one above another. For convenience of description, the circuit layer DP-CL is briefly illustrated as a single layer. The display layer DP-OLED may include the pixel defining layer PDL, light emitting elements ED including emissive layers EML disposed in a plurality of pixel openings PDL-OP defined in (or by) the pixel defining layer PDL, and the encapsulation layer TFL disposed on the light emitting elements ED.

In the display panel DP, the base layer BL may be a member which provides the base surface on which the display layer DP-OLED is disposed. The base layer BL may be rigid or flexible. The base layer BL may be a glass substrate, a metal substrate, or a polymer substrate. However, embodiments are not limited thereto, and the base layer BL may be an inorganic layer, an organic layer, or a composite layer.

The circuit layer DP-CL may be disposed on the base layer BL. The circuit layer DP-CL may include an insulating layer, a semiconductor pattern, a conductive pattern, and a signal line. The circuit layer DP-CL may include a plurality of transistors (not illustrated) which are formed of the semiconductor pattern, the conductive pattern, and the signal line. Each of the transistors (not illustrated) may include a control electrode, an input electrode, and an output electrode. For example, the circuit layer DP-CL may include a switching transistor and a drive transistor for driving the light emitting elements ED.

The display layer DP-OLED may be disposed on the circuit layer DP-CL. The display layer DP-OLED may include the pixel defining layer PDL, the light emitting elements ED, and the encapsulation layer TFL. In an embodiment, the display layer DP-OLED may include a plurality of light emitting elements ED-1, ED-2, and ED-3.

Each of the light emitting elements ED-1, ED-2, and ED-3 may include a first electrode EL1, a second electrode EL2 facing the first electrode EL1, and an emissive layer EML disposed between the first electrode EL1 and the second electrode EL2. In addition, although not illustrated, each of the light emitting elements ED-1, ED-2, and ED-3 may further include a hole transport area and an electron transport area. Each of the light emitting elements ED-1, ED-2, and ED-3 may further include a capping layer (not shown) disposed on the second electrode EL2.

In the display layer DP-OLED, the first light emitting element ED-1 may include the first emissive layer EML-R overlapping the first emissive area PXA-R, and the second light emitting element ED-2 may include the second emissive layer EML-G overlapping the second emissive area PXA-G. The third light emitting element ED-3 may include the third emissive layer EML-B overlapping the third emissive area PXA-B.

Meanwhile, the expression “two components overlap each other” used herein is not limited to the fact that the two components have the same (planar) area and the same shape when viewed from above a plane and includes the case in which the two components have different areas and/or different shapes. Here, for example, the two components overlap by facing each other along the third direction DR3. The plane means a plane perpendicular to a thickness direction.

The pixel defining layer PDL may be disposed on the circuit layer DP-CL. The plurality of pixel openings PDL-OP may be defined in the pixel defining layer PDL. At least portions of the first electrodes EL1 may be exposed to outside the pixel defining layer PDL, through the pixel openings PDL-OP of the pixel defining layer PDL, respectively.

The pixel openings PDL-OP defined in the pixel defining layer PDL may correspond to the emissive areas PXA-R, PXA-G, and PXA-B, respectively. That is, planar shapes, boundaries, etc. of the pixel openings PDL-OP may respectively correspond to the various emissive areas. The non-emissive area NPXA may be an area between the adjacent emissive areas PXA-R, PXA-G, and PXA-B and may be an area corresponding to the pixel defining layer PDL.

The pixel defining layer PDL may include an organic resin or an inorganic material. For example, the pixel defining layer PDL may include a polyacrylate-based resin, a polyimide-based resin, silicon nitride (SiNₓ), silicon oxide (SiOₓ), or silicon oxy nitride (SiOₓN_{y}).

In an embodiment, the pixel defining layer PDL may have a property of absorbing light. For example, the pixel defining layer PDL may be black in color. The pixel defining layer PDL may include a black coloring agent. The black coloring agent may include a black dye or a black pigment. The pixel defining layer PDL may correspond to a light blocking pattern having light-blocking characteristics.

In an embodiment, the emissive layers EML-R, EML-G, and EML-B of the light emitting elements ED-1, ED-2, and ED-3 and the second electrode EL2 may be subjected to patterning by an ink-jet printing method. That is, the various emissive layers may each be a discrete pattern of an emissive material.

In the display module DM according to an embodiment, the plurality of light emitting elements ED-1, ED-2, and ED-3 may emit light in different wavelength ranges. For example, in an embodiment, the display module DM may include the first light emitting element ED-1 which emits red light, the second light emitting element ED-2 which emits green light, and the third light emitting element ED-3 which emits blue light. That is, the red light emitting area PXA-R, the green light emitting area PXA-G, and the blue light emitting area PXA-B in the electronic device of an embodiment may correspond to the first light emitting element ED-1, the second light emitting element ED-2, and the third light emitting element ED-3, respectively. However, embodiments are not limited thereto, and the first to third light emitting elements ED-1, ED-2, and ED-3 may emit light in the same wavelength range, or at least one of the first to third light emitting elements ED-1, ED-2, and ED-3 may emit light in a different wavelength range. For example, the first to third light emitting elements ED-1, ED-2, and ED-3 may all emit blue light.

In the light emitting elements ED, the first electrodes EL1 may be disposed on the circuit layer DP-CL. The first electrodes EL1 may be anodes or cathodes. Furthermore, the first electrodes EL1 may be pixel electrodes. The first electrodes EL1 may be transmissive electrodes, transflective electrodes, or reflective electrodes. The various first electrodes EL1 may respectively be a discrete pattern of a conductive material layer.

The emissive layers EML may be respectively disposed on the first electrodes EL1. The emissive layers EML may include the plurality of emissive layers EML-R, EML-G, and EML-B. The first emissive layer EML-R may overlap the first emissive area PXA-R and may emit the first light. The second emissive layer EML-G may overlap the second emissive area PXA-G and may emit the second light. The third emissive layer EML-B may overlap the third emissive area PXA-B and may emit the third light. The first light, the second light, and the third light emitted from the light emitting elements ED-1, ED-2, and ED-3 according to an embodiment may be light in substantially different wavelength ranges. For example, the first light may be red light in the wavelength range of about 625 nanometers (nm) to about 675 nm, the second light may be green light in the wavelength range of about 500 nm to about 570 nm, and the third light may be blue light in the wavelength range of about 410 nm to about 480 nm.

The second electrode EL2 is provided on the emissive layers EML-R, EML-G, and EML-B. The second electrode EL2 may be a common electrode. The second electrode EL2 may be a cathode or an anode, but embodiments are not limited thereto. For example, when the first electrodes EL1 are anodes, the second electrode EL2 may be a cathode, and when the first electrodes EL1 are cathodes, the second electrode EL2 may be an anode. The second electrode EL2 may be a transmissive electrode, a transflective electrode, or a reflective electrode. The second electrode EL2 may be continuous across the emissive area and the non-emissive area NPXA, without being limited thereto.

The capping layer (not shown) may be further disposed on the second electrode EL2. In an embodiment, the capping layer may be an organic layer or an inorganic layer.

The encapsulation layer TFL may be disposed on the light emitting elements ED. The encapsulation layer TFL may be disposed to cover the light emitting elements ED. The encapsulation layer TFL may be disposed on the light emitting elements ED and may fill thickness portions of the pixel openings PDL-OP. The encapsulation layer TFL may include the first inorganic layer IL1, the organic layer OL, and the second inorganic layer IL2 sequentially stacked one above another.

According to an embodiment of the present disclosure, the patterns PT may be defined at an upper surface of the encapsulation layer TFL which is furthest from the display layer DP-OLED. The patterns PT may be concave patterns recessed toward the light emitting elements ED. The upper surface of the organic layer OL may be recessed toward the light emitting elements ED to form a cross-sectional shape of the patterns PT. Accordingly, recessed patterns may also be formed in the second inorganic layer IL2 since the second inorganic layer IL2 follows the cross-sectional shape of the underlying layer (e.g., the organic layer OL). The patterns PT may have a hemispherical shape on the cross-section and a closed shape in the plan view. A single one pattern PT may be provided in a same one emissive area, that is, in one-to-one correspondence.

Referring to FIGS. 6A and 6B together, the first thickness Th1 of the organic layer OL may be different from the second thickness Th2 of the optical layer OCL. For example, the first thickness Th1 of the organic layer OL may range from about 7000 nm to about 8000 nm, and the second thickness Th2 of the optical layer OCL may range from about 1500 nm to about 2500 nm. In the present disclosure, the first thickness Th1 of the organic layer OL and the second thickness Th2 of the optical layer OCL may each be the thickness at the center of the first emissive layer EML-R relative to an outer edge thereof.

In an embodiment, the first thickness Th1 of the organic layer OL may be the maximum thickness of the organic layer OL, and the second thickness Th2 of the optical layer OCL may be the maximum thickness of the optical layer OCL. That is, the organic layer OL and the optical layer OCL may each have the maximum thickness at the center of the first emissive layer EML-R. The first thickness Th1 of the organic layer OL may be greater than the sum of thicknesses of the first inorganic layer IL1 and the thickness of the second inorganic layer IL2 within the respective emissive area. For example, the thickness of the first inorganic layer IL1 may range from about 1000 nm to about 2000 nm, and the thickness of the second inorganic layer IL2 may range from about 300 nm to about 600 nm.

The refractive index of the first inorganic layer IL1 may range from about 1.5 to about 1.7, and the refractive index of the second inorganic layer IL2 may range from about 1.8 to about 2.0. Since the first thickness Th1 of the organic layer OL is greater than the sum of thicknesses of the first inorganic layer IL1 and the thickness of the second inorganic layer IL2, the refractive index of the encapsulation layer TFL may be substantially the same as the refractive index of the organic layer OL.

The width W1 of the pattern PT of the present disclosure may range from about 40 micrometers (μm) to about 60 μm. The width W1 of the pattern PT of the present disclosure may be greater than the width of the first emissive area PXA-R, along a same (planar) direction. However, the present disclosure is not limited thereto, and the width W1 of the pattern PT may be smaller than or equal to the width of the first emissive area PXA-R.

In an embodiment, the pattern PT may be formed by photolithography and etching in a method of providing the electronic device DD. However, the present disclosure is not limited thereto, and the pattern PT may be formed through an exposure process or a printing process.

The optical layer OCL may be disposed on the encapsulation layer TFL. Specifically, the optical layer OCL may be disposed on the second inorganic layer IL2 which defines the upper surface of the encapsulation layer TFL. The optical layer OCL may provide a flat upper surface. The input sensor ISU may be disposed on the flat upper surface of the optical layer OCL. The configuration of the input sensor ISU has been described above, and therefore description thereabout will be omitted. The optical layer OCL may include an organic material.

The color filter layer CFL may be disposed on the input sensor ISU. The color filter layer CFL may selectively transmit light. In an embodiment, the color filter layer CFL may be a low-reflection layer or an anti-reflective layer which decreases the reflectance of external light incident from outside the electronic device. In addition, the color filter layer CFL may selectively transmit a portion of provided light to improve the color gamut of the electronic device. The term “color gamut” used herein refers to the range of colors which the electronic device is able to display. For example, the color filter layer CFL may selectively absorb or transmit light in a specific wavelength range to improve the color gamut. Light incident to the display panel DP through the color filter layer CFL may be unpolarized light. The display panel DP may receive the unpolarized light from above the color filter layer CFL.

The color filter layer CFL may include a filter CF, and split patterns BM in which split openings OH-BM are defined to provide a light blocking layer. The split openings OH-BM may be defined to correspond to (or overlap) the pixel openings PDL-OP, respectively.

The filter CF may include a first color filter CF-R which transmits light of a first color, a second color filter CF-G which transmits light of a second color, and a third color filter CF-B which transmits light of a third color. For example, the first color filter CF-R may be a red filter, the second color filter CF-G may be a green filter, and the third color filter CF-B may be a blue filter.

Each of the first to third color filters CF-R, CF-G, and CF-B may include a photosensitive polymer resin and a colorant. Each of the first to third color filters CF-R, CF-G, and CF-B may include a pigment or a dye. The first color filter CF-R may include a first colorant, the second color filter CF-G may include a second colorant, and the third color filter CF-B may include a third colorant. The first color filter CF-R may include a red pigment or dye, the second color filter CF-G may include a green pigment or dye, and the third color filter CF-B may include a blue pigment or dye. Meanwhile, embodiments are not limited thereto, and the third color filter CF-B may not include a pigment or a dye. For example, the third color filter CF-B may be formed of a transparent photosensitive resin. The third color filter CF-B may be transparent. When the third color filter CF-B is formed of a transparent photosensitive resin, light which the third color filter CF-B transmits is not limited to the light of the third color.

The split patterns BM as solid portions of the light blocking layer may be disposed to overlap the boundaries between adjacent color filters among the first to third color filters CF-R, CF-G, and CF-B. The split patterns BM may be disposed to correspond to the non-emissive area NPXA, and the first to third color filters CF-R, CF-G, and CF-B may be disposed to correspond to the first emissive area PXA-R, the second emissive area PXA-G, and the third emissive area PXA-B, respectively. The split patterns BM may be spaced apart from one another in a direction along the input sensor ISU.

In an embodiment, the split patterns BM may be black matrixes which prevent a light leakage phenomenon. The split patterns BM as light blocking patterns of the light blocking layer may be formed of an organic light blocking material or an inorganic light blocking material which includes a black pigment or a black dye. The split patterns BM may distinguish the boundaries between the adjacent first to third color filters CF-R, CF-G, and CF-B. Alternatively, in an embodiment, the split patterns BM may be formed of a blue filter.

The color filter layer CFL may further include an overcoat layer OC. The overcoat layer OC may cover the filter CF and the split patterns BM. The overcoat layer OC may completely overlap the display layer DP-OLED. The upper surface of the overcoat layer OC may define the upper surface of the color filter layer CFL and may cover the front surface of the display panel DP to protect the display panel DP.

Referring to FIGS. 6A and 6B together, light L may be emitted from the first emissive layer EML-R. The light L may correspond to the first light (e.g., red light).

According to an embodiment of the present disclosure, the refractive index of the encapsulation layer TFL and the refractive index of the optical layer OCL may be different from each other. The refractive index of the encapsulation layer TFL may be defined as a first refractive index, and the refractive index of the optical layer OCL may be defined as a second refractive index. The first refractive index may be equal to the refractive index of the organic layer OL. That is, the first refractive index may be the refractive index of the organic layer OL. The difference between the first refractive index and the second refractive index may range from about 0.1 to about 1.0.

The pattern PT illustrated in FIG. 6B may have a concave shape which is recessed toward the first light emitting element ED-1. According to this embodiment, the second refractive index may be greater than the first refractive index. For example, the first refractive index may range from about 1.5 to about 1.7, and the second refractive index may range from about 1.8 to about 2.0. Since the refractive index of the optical layer OCL and the refractive index of the organic layer OL are different from each other, the light L may be refracted at the boundary or interface between the optical layer OCL and the organic layer OL. Specifically, since the refractive index of the refractive index layer of the encapsulation layer TFL (e.g., the organic layer OL considered together with the thinner dimension of the second inorganic layer IL2) is greater than the refractive index of the optical layer OCL, the light L may be concentrated at the center of the first color filter CF-R according to Snell's Law. The center of the first color filter CF-R may correspond to the center of the first emissive layer EML-R.

Referring to FIGS. 6A and 6B together, the light L may be emitted from the light emitting elements ED-1, ED-2, and ED-3. The light L emitted from the light emitting elements ED-1, ED-2, and ED-3 may be concentrated on the centers of the color filters CF-R, CF-G, and CF-B, respectively. Accordingly, mixing of the light L emitted from the light emitting elements ED-1, ED-2, and ED-3 at outer edges of the emissive areas may be prevented, and the electronic device DD (refer to FIG. 1) with improved light extraction efficiency may be provided.

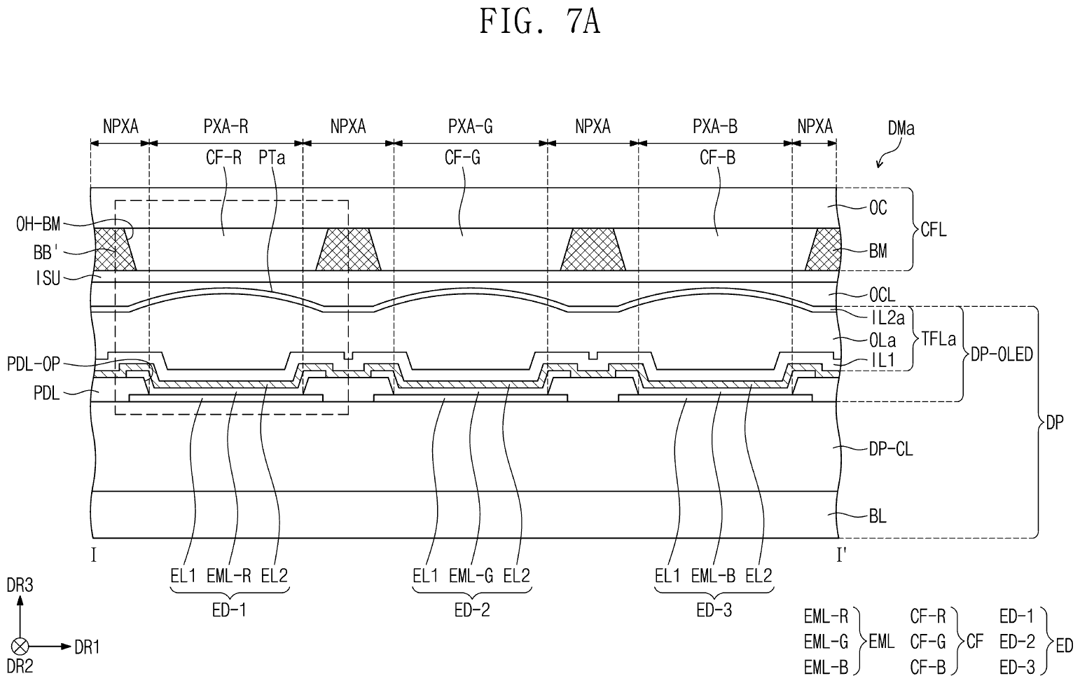

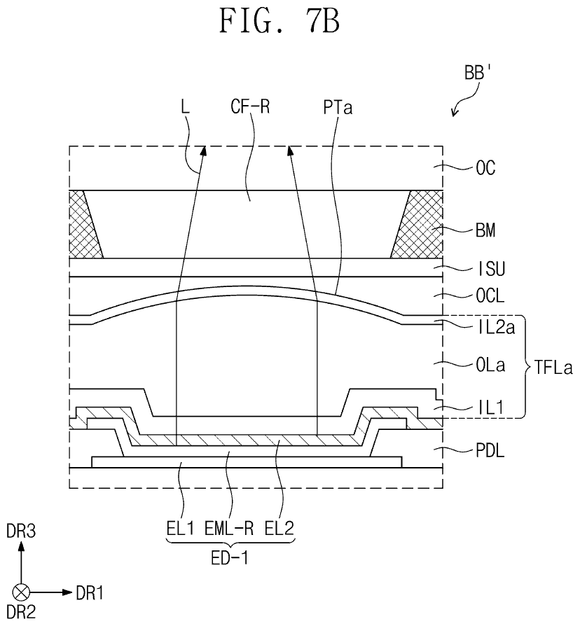

FIG. 7A is a cross-sectional view of a display module DMa corresponding to line I-I′ illustrated in FIG. 5 according to an embodiment of the present disclosure. FIG. 7B is an enlarged view of area BB′ illustrated in FIG. 7A. Hereinafter, components identical/similar to the components described above will be assigned with identical/similar reference numerals, and repetitive description will be omitted.

Referring to FIGS. 7A and 7B together, the display module DMa according to an embodiment of the present disclosure may include an encapsulation layer TFLa disposed on light emitting elements ED. The encapsulation layer TFLa may include a first inorganic layer IL1, an organic layer OLa, and a second inorganic layer IL2a sequentially stacked one above another.

According to an embodiment of the present disclosure, patterns PTa may be defined in the encapsulation layer TFLa. The patterns PTa may have a shape which protrudes in the direction away from the light emitting elements ED, e.g., a convex shape relative to the display layer DP-OLED. Hereinafter, the patterns PTa may be referred to as the protruding patterns PTa. The upper surface of the organic layer OLa may protrude in the direction away from the light emitting elements ED at locations of the organic layer OLa which overlap the various emissive areas, to form the protruding patterns PTa. Accordingly, protruding patterns may also be formed in the second inorganic layer IL2a owing to the underlying cross-sectional shape of the organic layer OLa.

The refractive index of the organic layer OLa may be defined as a first refractive index, and the refractive index of an optical layer OCL may be defined as a second refractive index. According to this embodiment, the first refractive index may be greater than the second refractive index. For example, the first refractive index may range from about 1.8 to about 2.0, and the second refractive index may range from about 1.5 to about 1.7. Since the refractive index of the optical layer OCL and the refractive index of the organic layer OLa are different from each other, light L may be refracted at the boundary between the optical layer OCL and the organic layer OLa. Specifically, since the refractive index of the organic layer OLa on which the protruding patterns PTa are formed is smaller than the refractive index of the optical layer OCL, the light L may be concentrated on the center of a first color filter CF-R according to Snell's Law. Thus, mixing of the light L emitted from the light emitting elements ED-1, ED-2, and ED-3 at outer edges of the various emissive areas may be prevented, and the electronic device DD (refer to FIG. 1) with improved light extraction efficiency may be provided.

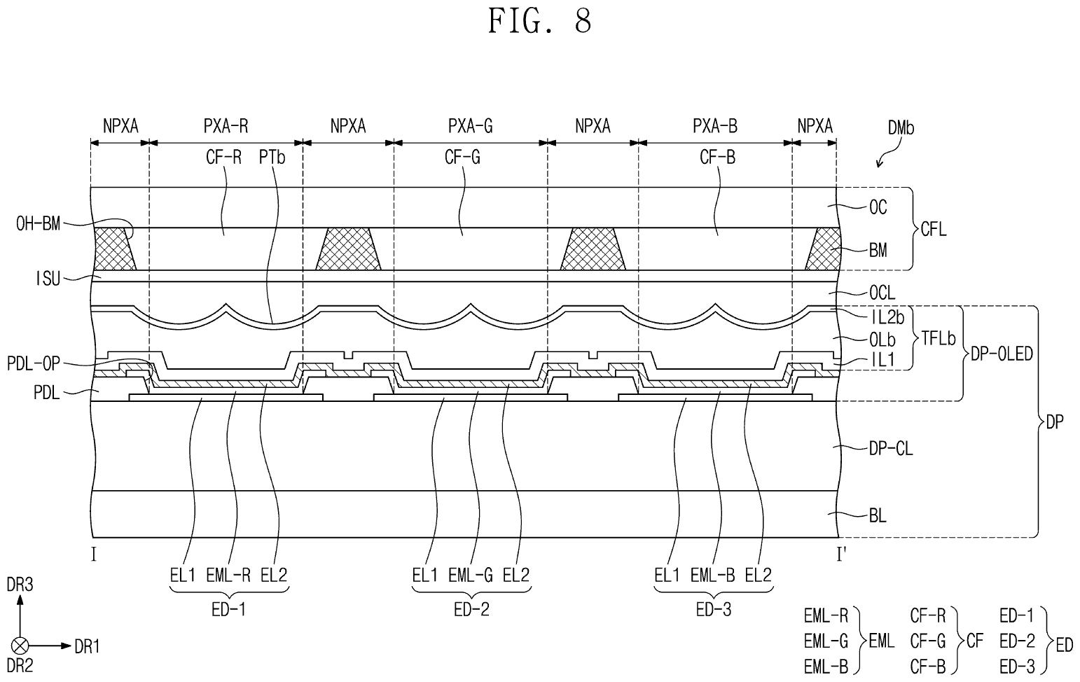

FIG. 8 is a cross-sectional view of a display module DMb corresponding to line I-I′ illustrated in FIG. 5 according to an embodiment of the present disclosure.

Referring to FIG. 8, the display module DMb according to an embodiment of the present disclosure may include an encapsulation layer TFLb disposed on light emitting elements ED. The encapsulation layer TFLb may include a first inorganic layer IL1, an organic layer OLb, and a second inorganic layer IL2b sequentially stacked one above another.

According to an embodiment of the present disclosure, a pattern PTb may be defined in the encapsulation layer TFLb. A plurality of patterns PTb may be provided. That is, more than one pattern PTb may be provided in a same one emissive area. For example, the plurality of patterns PTb may be provided in each of first to third emissive areas PXA-R, PXA-G, and PXA-B. Although FIG. 8 illustrates an example that two patterns PTb are formed in each of the first to third emissive areas PXA-R, PXA-G, and PXA-B, the present disclosure is not limited thereto, and three or more patterns PTb may be formed in each of the first to third emissive areas PXA-R, PXA-G, and PXA-B.

Referring to FIGS. 6A, 6B, 7A, 7B and 8, a pattern PT may have a recessed or a protruded shape defined by a curved surface of the organic layer OL and/or the second inorganic layer IL2. The recessed or protruded shape may be defined by a continuously curved shape, without being limited thereto. In an embodiment, the recessed or protruded shape may be defined by linear portions connected to each other, different from the curved shape.

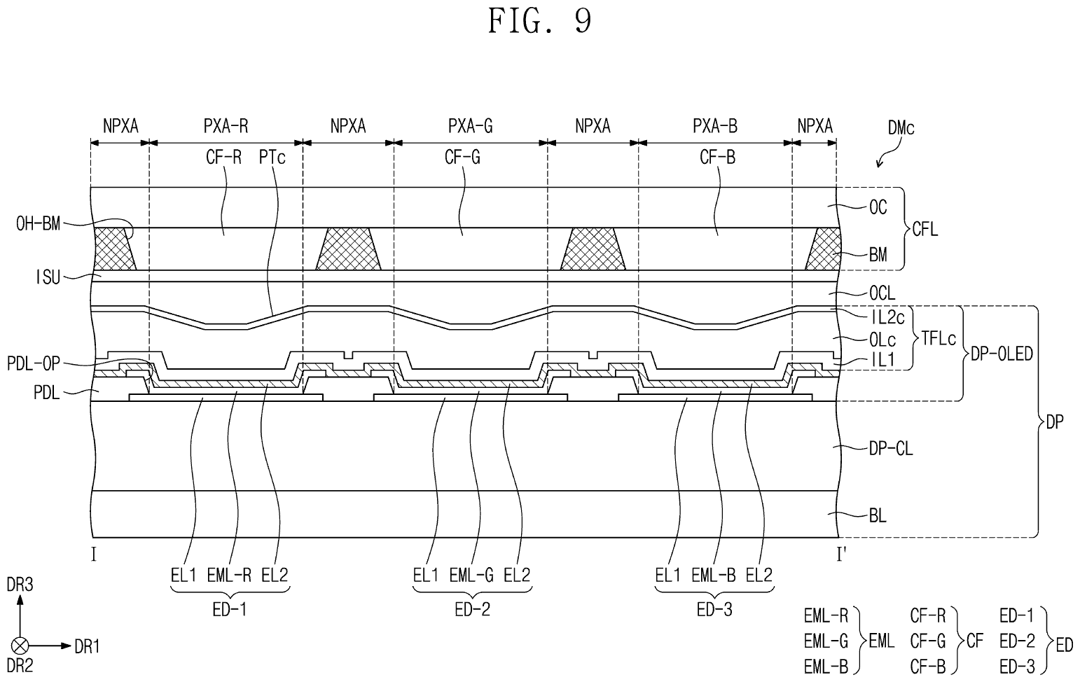

FIG. 9 is a cross-sectional view of a display module DMc corresponding to line I-I′ illustrated in FIG. 5 according to an embodiment of the present disclosure.

Referring to FIG. 9, the display module DMc according to an embodiment of the present disclosure may include an encapsulation layer TFLc disposed on light emitting elements ED. The encapsulation layer TFLc may include a first inorganic layer IL1, an organic layer OLc, and a second inorganic layer IL2c sequentially stacked one above another.

According to an embodiment of the present disclosure, patterns PTc may be defined on the encapsulation layer TFLc. The patterns PTc may have a concave shape recessed toward the light emitting elements ED. Each of the patterns PTc may have a trapezoidal shape on the cross-section. For example, the pattern PTc may include a flat lower surface and two inclined surfaces extending from the lower surface.

An electronic device DD according to an embodiment of the present disclosure includes a display module DM and a power module which supplies power to the display module DM.

The display devices 10 and 20 according to embodiments of the present disclosure may be applied to various electronic devices. An electronic device according to an embodiment of the present disclosure may include the display device 10 or the display device 20 described above, and may further include a module or device having additional functions in addition to the display device 10 or the display device 20.

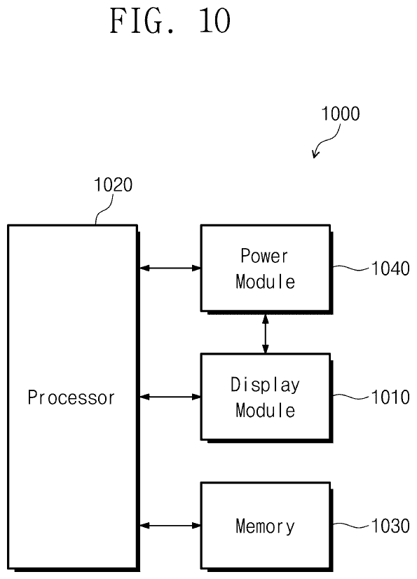

FIG. 10 is a block diagram illustrating an electronic device 1000 according to an embodiment of the present disclosure. One or more embodiment of the electronic device DD described above may be represented by FIG. 10.

Referring to FIG. 10, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module which converts power supplied by the power supply module to generate power necessary for an operation of the electronic device 1000.

At least one of the components of the electronic device 1000 described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

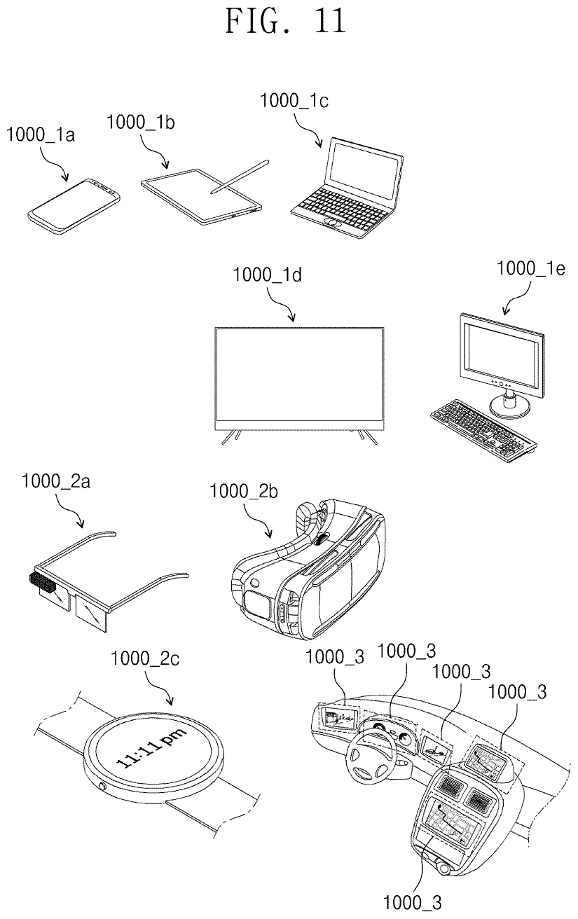

FIG. 11 is a schematic view of electronic devices according to embodiments of the present disclosure.

Referring to FIG. 11, various electronic devices to which the display device according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The electronic device DD of the present disclosure may include the encapsulation layer TFL which has the first refractive index and in which the concave pattern or the convex pattern is formed, together with the optical layer OCL which is disposed on the encapsulation layer TFL and that has the second refractive index different from the first refractive index. Accordingly, the electronic device DD may prevent mixing of light emitted from the light emitting elements ED and may improve light extraction efficiency at the various emissive areas.

In an embodiment, an electronic device DD includes a display layer DP-OLED including emissive areas each including a light emitting element, and a non-emissive area NPXA which is adjacent to the emissive areas, an encapsulation layer TFL which is on the display layer DP-OLED, the encapsulation layer TFL defining a concave pattern or a convex pattern which overlaps an emissive area among the emissive areas together with having a width of about 40 micrometers to about 60 micrometers in a direction along the display layer DP-OLED and having a first refractive index, and an optical layer OCL which is on the encapsulation layer TFL and has a second refractive index different from the first refractive index.

The encapsulation layer TFL may include the concave pattern recessed toward the light emitting element together with the second refractive index being greater than the first refractive index. The first refractive index may range from about 1.5 to about 1.7 together with the second refractive index ranging from about 1.8 to about 2.0.

The encapsulation layer TFL may include the convex pattern protruded away from the light emitting element together with the first refractive index being greater than the second refractive index. The first refractive index may range from about 1.8 to about 2.0 together with the second refractive index ranging from about 1.5 to about 1.7.

The encapsulation layer may include an organic layer OL which is on a first inorganic layer IL1 and defines the first refractive index. The encapsulation layer TFL may further include the organic layer OL having the first refractive index together with having a thickness greater than thicknesses of each of the first inorganic layer IL1 and the second inorganic layer IL2. The thickness of the organic layer OL may range from about 7000 nm to about 8000 nm. The encapsulation layer TFL may further include the second inorganic layer IL2 having a refractive index greater than a refractive index of the first inorganic layer IL1.

The electronic device DD may further include a color filter layer CFL which includes color filters CF respectively corresponding to the emissive areas, and the concave pattern or the convex pattern may overlap a color filter among the color filters.

The encapsulation layer may include the concave pattern or the convex pattern provided in plural, and one concave pattern among the concave patterns or one convex pattern among the convex patterns may overlap one emissive area among the emissive areas.

In an embodiment, an electronic device DD includes an encapsulation layer TFLb which is on the display layer DP-OLED, the encapsulation layer TFLb defining a concave pattern which is recessed toward the light emitting element together with overlapping an emissive area among the emissive areas and having a first refractive index, and an optical layer OCL which is on the encapsulation layer TFLb and has a second refractive index greater than the first refractive index of the encapsulation layer.

The encapsulation layer TFLb may include the concave pattern provided in plural, and two or more concave patterns among the concave patterns overlapping one emissive area among the emissive areas.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a display layer including emissive areas each including a light emitting element, and a non-emissive area which is adjacent to the emissive areas;
an encapsulation layer which is on the display layer, the encapsulation layer defining a concave pattern or a convex pattern which overlaps an emissive area among the emissive areas together with having a width of about 40 micrometers to about 60 micrometers in a direction along the display layer and having a first refractive index; and
an optical layer which is on the encapsulation layer and has a second refractive index different from the first refractive index of the encapsulation layer.

2. The electronic device of claim 1, wherein the encapsulation layer includes the concave pattern recessed toward the light emitting element together with the second refractive index being greater than the first refractive index.

3. The electronic device of claim 2, wherein the first refractive index ranges from about 1.5 to about 1.7 together with the second refractive index ranging from about 1.8 to about 2.0.

4. The electronic device of claim 1, wherein the encapsulation layer includes the convex pattern protruded away from the light emitting element together with the first refractive index being greater than the second refractive index.

5. The electronic device of claim 4, wherein the first refractive index ranges from about 1.8 to about 2.0 together with the second refractive index ranging from about 1.5 to about 1.7.

6. The electronic device of claim 1, wherein the encapsulation layer includes:
a first inorganic layer on the light emitting element;
an organic layer which is on the first inorganic layer and defines the first refractive index; and
a second inorganic layer on the organic layer.

7. The electronic device of claim 6, wherein the encapsulation layer includes the organic layer having the first refractive index together with having a thickness greater than thicknesses of each of the first inorganic layer and the second inorganic layer.

8. The electronic device of claim 7, wherein the thickness of the organic layer ranges from about 7000 nanometer to about 8000 nanometers.

9. The electronic device of claim 6, wherein the encapsulation layer further includes the second inorganic layer having a refractive index greater than a refractive index of the first inorganic layer.

10. The electronic device of claim 1, wherein the optical layer includes a flat upper surface.

11. The electronic device of claim 10, further comprising a color filter layer on the upper surface of the optical layer.

12. The electronic device of claim 11, wherein
the color filter layer includes color filters respectively corresponding to the emissive areas, and
the concave pattern or the convex pattern overlaps a color filter among the color filters.

13. The electronic device of claim 1, wherein a difference between the first refractive index and the second refractive index ranges from about 0.1 to about 1.0.

14. The electronic device of claim 1, wherein the encapsulation layer includes:
the concave pattern or the convex pattern provided in plural, and
one concave pattern among the concave patterns or one convex pattern among the convex patterns overlapping one emissive area among the emissive areas.

15. The electronic device of claim 1, wherein the optical layer includes an organic material.

16. The electronic device of claim 1, wherein the optical layer has a thickness of about 1500 nanometers to about 2500 nanometers.

17. An electronic device comprising:
a display layer including emissive areas each including a light emitting element, and a non-emissive area which is adjacent to the emissive areas;
an encapsulation layer which is on the display layer, the encapsulation layer defining a concave pattern which is recessed toward the light emitting element together with overlapping an emissive area among the emissive areas and having a first refractive index; and
an optical layer which is on the encapsulation layer and has a second refractive index greater than the first refractive index of the encapsulation layer.

18. The electronic device of claim 17, wherein the first refractive index of the encapsulation layer ranges from about 1.5 to about 1.7 together with the second refractive index of the optical layer ranging from about 1.8 to about 2.0.

19. The electronic device of claim 17, wherein the encapsulation layer includes:
a first inorganic layer on the light emitting element;
an organic layer which is on the first inorganic layer and defines the first refractive index; and
a second inorganic layer on the organic layer.

20. The electronic device of claim 17, wherein the encapsulation layer includes:
the concave pattern provided in plural, and
two or more concave patterns among the concave patterns overlapping one emissive area among the emissive areas.
